(19) United States
(12) Patent Application Publication
(10) Pub. No.: US 2015/0008970 A1
(43) Pub. Date: Jan. 8, 2015

(54) PERIOD SIGNAL GENERATION CIRCUIT

(71) Applicant: SK hynix Inc., Icheon-si (KR)

(72) Inventor: Man Keun KANG, Seongnam-si (KR)

(73) Assignee: SK hynix Inc., Icheon-si (KR)

(21) Appl. No.: 14/133,993

(22) Filed: Dec. 19, 2013

(30) Foreign Application Priority Data
Jul. 5, 2013 (KR) 10-2013-0079241

(51) Int. Cl. H03K 3/011

(52) U.S. Cl. CPC H03K 3/011
USPC 327/291

(57) ABSTRACT

A period signal generation circuit includes a first buffer unit suitable for buffering a buffer signal and output an output signal; and a second buffer unit suitable for buffering the output signal and output a period signal, wherein each of the first and second buffer units includes a resistor element coupled between a body of a metal oxide semiconductor (MOS) transistor and a source.

### CROSS-REFERENCES TO RELATED APPLICATIONS

The present application claims priority under 35 U.S.C 119(a) to Korean Patent Application No. 10-2013-0079241 filed on Jul. 5, 2013 in the Korean Intellectual Property Office, which is incorporated herein by reference in its entirety set forth in full.

### BACKGROUND

1. Field of the Invention

Various embodiments of the invention relate to a period signal generation circuit.

2. Discussion of Related Art

Recently, as the threshold voltage of a transistor is set low for a high speed operation of an integrated circuit, leakage current markedly increases. Therefore, in an integrated circuit operating at a high speed, an SOI (silicon-on-insulator) process is applied to reduce leakage current. If the SOI process is applied, because the channel region of the transistor is electrically isolated from the underlying layer of a wafer, the body of the transistor is floated. As a result, since the transistor does not have any substantial parasitic capacitance, there is no leakage current flowing to a substrate, by which appropriateness for a high speed operation is rendered. However, in the case of the SOI process, integration is difficult and commercialization is difficult due to high costs. Although leakage current may be reduced by raising a threshold voltage through applying a reverse bias to the body terminal of a transistor, since the switching speed of the transistor becomes slow, limitations exist to be used for a high speed operation.

Meanwhile, an integrated circuit internally needs a period signal to perform various internal operations. In a semiconductor device, a period signal is generated by a period signal generation circuit such as an oscillator and is used to control a refresh operation, an internal voltage pumping operation, and so forth. Because the period signal generation circuit includes a plurality of transistors, an issue is raised in terms of leakage current at a high speed operation.

### SUMMARY

Embodiments of the invention relate to a period signal generation circuit capable of reducing leakage current.

In an embodiment, a period signal generation circuit includes: a first buffer unit suitable for buffering a buffer signal and output an output signal; and a second buffer unit suitable for buffering the output signal and output a period signal, wherein each of the first and second buffer units includes at least one MOS transistor with a resistor element coupled between a body of a metal oxide semiconductor (MOS) transistor and a source.

In an embodiment, a period signal generation circuit includes: a first buffer unit suitable for buffering a buffer signal and output an output signal; a second buffer unit suitable for buffering the output signal and output a period signal; and a first resistor unit including a first resistor element coupled to a first power supply voltage, wherein each of the first and second buffer units includes a body of a MOS transistor coupled to the first resistor element or a second resistor element.

In an embodiment, a period signal generation circuit includes: a first buffer unit suitable for buffering a buffer signal and output an output signal; a second buffer unit suitable for buffering the output signal and output a period signal; and a resistor unit including a first resistor element coupled to a first ground voltage, wherein each of the first and second buffer units includes a body of a MOS transistor coupled to the first resistor element or a second resistor element.

In an embodiment, a microprocessor comprises: a control unit suitable for receiving a signal including a command and perform an extraction or a decryption of the command or input or output control; an operation unit suitable for performing an operation according to a decryption result of the command in the control unit; and a storage unit suitable for storing one or more among data to be operated, data corresponding to a result of the operation, and an address for the data to be operated, wherein the storage unit includes: a first buffer unit suitable for buffering a buffer signal and output an output signal; a second buffer unit suitable for buffering the output signal and output a period signal, wherein each of the first and second buffer units include a resistor element coupled between a body of a MOS transistor and a source.

Thanks to the above embodiments, since resistors are coupled with the bodies of transistors, parasitic capacitance may be reduced, whereby it is possible to reduce leakage current.

Also, in the embodiments of the present disclosure, since resistors are coupled with the bodies of transistors, the bodies of the transistors may have specific resistance values, whereby it is possible to prevent a latch-up phenomenon from occurring due to floating of the bodies of transistors.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram showing the configuration of a period signal generation circuit in accordance with an embodiment; and

FIG. 2 is a block diagram showing the configuration of a period signal generation circuit in accordance with an embodiment.

FIG. 3 is a block diagram illustrating a microprocessor according to an embodiment of the invention.

### DESCRIPTION OF SPECIFIC EMBODIMENTS

Hereinafter, embodiments of the invention will be described with reference to accompanying drawings. However, the embodiments are for illustrative purposes only and are not intended to limit the scope of the invention.

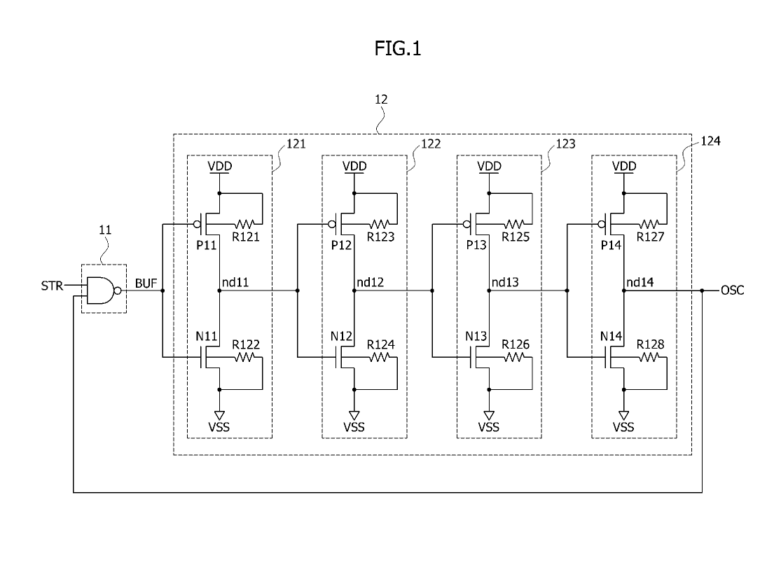

Referring to FIG. 1, a period signal generation circuit in accordance with an embodiment of the disclosure includes a buffer element 11 and a buffer block 12. The buffer element 11 is suitable for inversion-buffering a period signal OSC in response to a start signal STR and generate a buffer signal BUF. The start signal STR, as a signal which is inputted at a logic high level to activate the operation of the period signal generation circuit, may be inputted externally or may be generated internally. The buffer block 12 includes a first buffer unit 121, a second buffer unit 122, a third buffer unit 123, and a fourth buffer unit 124.

The first buffer unit 121 includes a p-type metal oxide semiconductor (PMOS) transistor P11 operating as a pull-up element which pull-up drives a node nd11 in response to the buffer signal BUF, and an n-type metal oxide semiconductor (NMOS) transistor N11 operating as a pull-down element which pull-down drives the node nd11 in response to the buffer signal BUF. The first buffer unit 121 may be suitable for buffering the buffer signal BUF and output an output signal to the node nd11. A resistor element R121 is coupled between the body of the PMOS transistor P11 and a power supply voltage VDD. A resistor element R122 is coupled between the body of the NMOS transistor N11 and a ground voltage VSS. The second buffer unit 122 includes a PMOS transistor P12 operating as a pull-up element which pull-up drives a node nd12 in response to the output signal of the first buffer unit 121, and an NMOS transistor N12 operating as a pull-down element which pull-down drives the node nd12 in response to the output signal of the first buffer unit 121. The second buffer unit 122 may be suitable for buffering the output signal of the first buffer unit 121 and output a period signal. A resistor element R123 is coupled between the body of the PMOS transistor P12 and the power supply voltage VDD. A resistor element R124 is coupled between the body of the NMOS transistor N12 and the ground voltage VSS. The third buffer unit 123 includes a PMOS transistor P13 operating as a pull-up element which pull-up drives a node nd13 in response to the output signal of the second buffer unit 122, and an NMOS transistor N13 operating as a pull-down element which pull-down drives the node nd13 in response to the output signal of the second buffer unit 122. A resistor element R125 is coupled between the body of the PMOS transistor P13 and the power supply voltage VDD. A resistor element R126 is coupled between the body of the NMOS transistor N13 and the ground voltage VSS. The fourth buffer unit 124 includes a PMOS transistor P14 operating as a pull-up element which pull-up drives a node nd14 from which the period signal OSC is outputted, in response to the output signal of the third buffer unit 123, and an NMOS transistor N14 operating as a pull-down element which pull-down drives the node nd14 in response to the output signal of the third buffer unit 123. A resistor element R127 is coupled between the body of the PMOS transistor P14 and the power supply voltage VDD. A resistor element R128 is coupled between the body of the NMOS transistor N14 and the ground voltage VSS.

The period signal generation circuit configured as mentioned above generates the period signal OSC which has a predetermined cycle, in the case where the start signal STR is enabled to the logic high level. The resistor elements R121, R123, R125 and R127 are coupled between the bodies of the PMOS transistors P11 to P14 included in the buffer block 12 of the period signal generation circuit and the power supply voltage VDD. Further, the resistor elements R122, R124, R126 and R128 are coupled between the bodies of the NMOS transistors N11 to N14 included in the buffer block 12 of the period signal generation circuit and the ground voltage VSS. As resistors are coupled to the bodies of the PMOS transistors P11 to P14 and the NMOS transistors N11 to N14, parasitic capacitance viewed on the bodies may be reduced, whereby leakage current may be reduced. Since the respective resistor elements R121 to R128 have specific resistance values, it is possible to prevent a latch-up phenomenon from occurring due to floating of the bodies of the PMOS transistors P11 to P14 and the NMOS transistors N11 to N14.

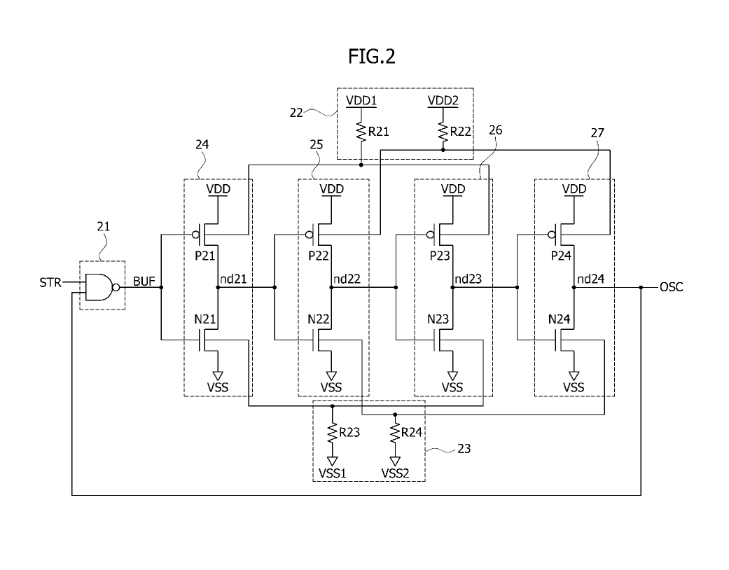

Referring to FIG. 2, a period signal generation circuit in accordance with an embodiment of the disclosure includes a buffer element 21, a first resistor unit 22, a second resistor unit 23, a first buffer unit 24, a second buffer unit 25, a third buffer unit 26, and a fourth buffer unit 27. The buffer element 21 is suitable for inversion-buffering a period signal OSC in response to a start signal STR and generate a buffer signal BUF. The start signal STR, as a signal which is inputted at a logic high level to activate the operation of the period signal generation circuit, may be inputted externally or may be generated internally. The first resistor unit 22 includes a resistor element R21 which is coupled to a first power supply voltage VDD1, and a resistor element R22 which is coupled to a second power supply voltage VDD2. The first power supply voltage VDD1 and the second power supply voltage VDD2 may be set to have the same level or different levels according to an embodiment. The resistor element R21 and the resistor element R22 may be set to have the same resistance value or different resistance values according to an embodiment. The second resistor unit 23 includes a resistor element R23 which is coupled to a first ground voltage VSS1, and a resistor element R24 which is coupled to a second ground voltage VSS2. The first ground voltage VSS1 and the second ground voltage VSS2 may be set to have the same level or different levels according to an embodiment. The resistor element R23 and the resistor element R24 may be set to have the same resistance value or different resistance values according to an embodiment.

The first buffer unit 24 includes a PMOS transistor P21 operating as a pull-up element which pull-up drives a node nd21 in response to the buffer signal BUF, and an NMOS transistor N21 operating as a pull-down element which pull-down drives the node nd21 in response to the buffer signal BUF. The first buffer unit 24 may be suitable for buffering the buffer signal BUF and output an output signal to the node nd21. The body of the PMOS transistor P21 is coupled to the resistor element R21. The body of the NMOS transistor N21 is coupled to the resistor element R23. The first buffer unit 24 may include a power supply voltage VDD and ground voltage VSS. The second buffer unit 25 includes a PMOS transistor P22 operating as a pull-up element which pull-up drives a node nd22 in response to the output signal of the first buffer unit 24; and an NMOS transistor N22 operating as a pull-down element which pull-down drives the node nd22 in response to the output signal of the first buffer unit 24. The second buffer unit 25 may be suitable for buffering the output signal of the first buffer unit 24 and output a period signal. The body of the PMOS transistor P22 is coupled to the resistor element R22. The body of the NMOS transistor N22 is coupled to the resistor element R24. The second buffer unit 25 may also include a power supply voltage VDD and ground voltage VSS. The third buffer unit 26 includes a PMOS transistor P23 operating as a pull-up element which pull-up drives a node nd23 in response to the output signal of the second buffer unit 25; and an NMOS transistor N23 operating as a pull-down element which pull-down drives the node nd23 in response to the output signal of the second buffer unit 25. The body of the PMOS transistor P23 is coupled to the resistor element R21. The body of the NMOS transistor N23 is coupled to the resistor element R23. The third buffer unit 26 may include a power supply voltage VDD and ground voltage VSS. The fourth buffer unit 27 includes a PMOS transistor P24 operating as a pull-up element which pull-up drives a node nd24 in response to the output signal of the third buffer unit 26; and an NMOS transistor N24 operating as a pull-down element which pull-down drives the node nd24 in response to the output signal of the third buffer unit 26. The body of the PMOS transistor P24 is coupled to the resistor element R22. The body of the NMOS transistor N24 is coupled to the resistor element R24. The fourth buffer unit 27 may also include a power supply voltage VDD and ground voltage VSS.

The period signal generation circuit configured as mentioned above generates the period signal OSC which has a predetermined cycle, in the case where the start signal STR is enabled to the logic high level. The resistor elements R21 and R22 are coupled between the bodies of the PMOS transistors P21 to P24 included in the period signal generation circuit and the first power supply voltage VDD1 and the second power supply voltage VDD2. Further, the resistor elements R23 and R24 are coupled between the bodies of the NMOS transistors N21 to N24 included in the period signal generation circuit and the first ground voltage VSS1 and the second ground voltage VSS2. As resistors are coupled to the bodies of the PMOS transistors P21 to P24 and the NMOS transistors N21 to N24, parasitic capacitance viewed on the bodies may be reduced, whereby leakage current may be reduced. Since the respective resistor elements R21 to R24 have specific resistance values, it is possible to prevent a latch-up phenomenon from occurring due to floating of the bodies of the PMOS transistors P21 to P24 and the NMOS transistors N21 to N24. Moreover, the period signal generation circuit in accordance with an embodiment shares the resistor elements R21 to R24 unlike the period signal generation circuit shown in FIG. 1. Accordingly, a layout area may be reduced.

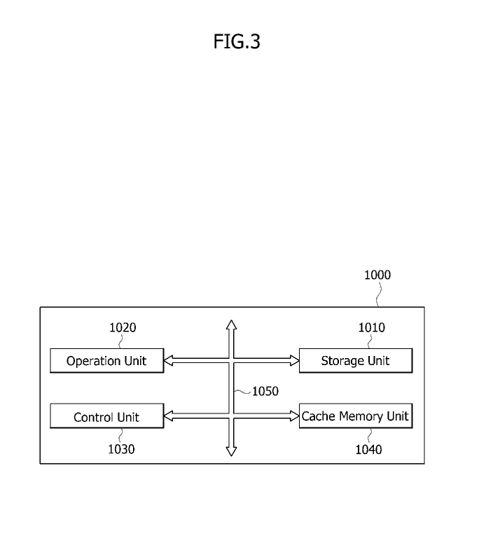

Referring to FIG. 3, a microprocessor 1000 to which the period signal generation unit may be applied may control and adjust a series of processes, which receive data from various external apparatuses, process the data and transmit processing results to the external apparatuses. The microprocessor 1000 may include a storage unit 1010, an operation unit 1020, and a control unit 1030. The microprocessor 1000 may be a variety of processing apparatuses, such as a central processing unit (CPU), a graphic processing unit (GPU), a digital signal processor (DSP), or an application processor (AP).

The storage unit 1010 may be a processor register or a register, and the storage unit 1010 may be a unit that may store data in the microprocessor 1000 and include a data register, an address register, and a floating point register. The storage unit 1010 may include registers other than the above-described registers. The storage unit 1010 may temporarily store data to be operated in the operation unit 1020, resulting data performed in the operation unit 1020, and an address in which data to be operated is stored. The storage unit 1010 may include the period signal generation unit.

The operation unit 1010 may perform an operation in the microprocessor 1000, and perform a variety of four fundamental rules of an arithmetic operation or a logic operation depending on a decryption result of a command in the control unit 1030. The operation unit 1020 may include one or more arithmetic and logic units (ALU).

The control unit 1020 may receive a signal from the storage unit 1010, the operation unit 1020, or an external apparatus of the microprocessor, perform extraction or decryption of a command, or input or output control, and execute a process in a program form.

The microprocessor 1000 according to an embodiment may further include a cache memory unit 1040 suitable for temporarily storing data input from an external apparatus other than the storage unit 1010 or data to be output to an external apparatus. The cache memory unit 1040 may exchange data from the storage unit 1010, the operation unit 1020, and the control unit 1030 through a bus interface 1050.

The embodiments of the invention have been disclosed above for illustrative purposes. Those skilled in the art will appreciate that various modifications, additions and substitutions are possible, without departing from the scope and spirit of the invention as disclosed in the accompanying claims.

What is claimed is:

1. A period signal generation circuit comprising:
a first buffer unit suitable for buffering a buffer signal and output an output signal; and
a second buffer unit suitable for buffering the output signal and output a period signal,
wherein each of the first and second buffer units includes a resistor element coupled between a body of a metal oxide semiconductor (MOS) transistor and a source.

2. The period signal generation circuit according to claim 1, wherein the first buffer unit comprises a first pull-up element realized by a first MOS transistor which pull-up drives an internal node in response to the buffer signal, and a resistor element is coupled between a body of the first MOS transistor and a power supply voltage.

3. The period signal generation circuit according to claim 2, wherein the first buffer unit further comprises a first pull-down element realized by a second MOS transistor which pull-down drives the internal node in response to the buffer signal, and a resistor element is coupled between a body of the second MOS transistor and a ground voltage.

4. The period signal generation circuit according to claim 3, wherein the second buffer unit comprises a second pull-up element realized by a third MOS transistor which pull-up drives the period signal in response to the output signal of the first buffer unit, and a resistor element is coupled between a body of the third MOS transistor and the power supply voltage.

5. The period signal generation circuit according to claim 4, wherein the second buffer unit further comprises a second pull-down element realized by a fourth MOS transistor which pull-down drives the period signal in response to the output signal of the first buffer unit, and a resistor element is coupled between a body of the fourth MOS transistor and the ground voltage.

6. A period signal generation circuit comprising:
a first buffer unit suitable for buffering a buffer signal and output an output signal;
a second buffer unit suitable for buffering the output signal and output a period signal; and
a first resistor unit including a first resistor element coupled to a first power supply voltage,
wherein each of the first and second buffer units includes a body of a metal oxide semiconductor (MOS) transistor coupled to the first resistor element or a second resistor element.

7. The period signal generation circuit according to claim 6, wherein the first buffer unit comprises a first pull-up element realized by a first MOS transistor which pull-up drives an internal node in response to the buffer signal, and a body of the first MOS transistor is coupled to the first resistor element.

8. The period signal generation circuit according to claim 7, wherein the second buffer unit comprises a second pull-up element realized by a second MOS transistor which pull-up drives the period signal in response to the output signal of the first buffer unit, and a body of the second MOS transistor is coupled to a second resistor element.

9. The period signal generation circuit according to claim 6, wherein the first resistor unit further includes the second resistor element which is coupled to a second power supply voltage.

10. The period signal generation circuit according to claim 9, wherein the first buffer unit comprises a first pull-up element realized by a first MOS transistor which pull-up drives the internal node in response to the buffer signal, and a body of the first MOS transistor is coupled to the first resistor element.

11. The period signal generation circuit according to claim 10, wherein the second buffer unit comprises a second pull-up element realized by a second MOS transistor which pull-up drives the period signal in response to the output signal of the first buffer unit, and a body of the second MOS transistor is coupled to the second resistor element.

12. The period signal generation circuit according to claim 6, further comprising:
a second resistor unit including the second resistor element which is coupled to a ground voltage.

13. The period signal generation circuit according to claim 12, wherein the first buffer unit further comprises a first pull-down element realized by a first MOS transistor which pull-down drives the internal node in response to the buffer signal, and a body of the first MOS transistor is coupled to the second resistor element.

14. The period signal generation circuit according to claim 13, wherein the second buffer unit further comprises a second pull-down element realized by a second MOS transistor which pull-down drives the period signal in response to the output signal of the first buffer unit, and a body of the second MOS transistor is coupled to a third resistor element.

15. A period signal generation circuit comprising:
a first buffer unit suitable for buffering a buffer signal and output an output signal;
a second buffer unit suitable for buffering the output signal and output a period signal; and
a resistor unit including a first resistor element coupled to a first ground voltage,
wherein each of the first and second buffer units includes a body of a MOS transistor coupled to the first resistor element or a second resistor element.

16. The period signal generation circuit according to claim 15, wherein the first buffer unit comprises a first pull-down element realized by a first MOS transistor which pull-down drives an internal node in response to the buffer signal, and a body of the first MOS transistor is coupled to the first resistor element.

17. The period signal generation circuit according to claim 16, wherein the second buffer unit comprises a second pull-down element realized by a second MOS transistor which pull-down drives the period signal in response to the output signal of the first buffer unit, and a body of the second MOS transistor is coupled to the second resistor element.

18. The period signal generation circuit according to claim 15, wherein the resistor unit further includes the second resistor element which is coupled to a second ground voltage.

19. The period signal generation circuit according to claim 18, wherein the first buffer unit comprises a first pull-down element realized by a first MOS transistor which pull-down drives an internal node in response to the buffer signal, and a body of the first MOS transistor is coupled to the first resistor element.

20. The period signal generation circuit according to claim 19, wherein the second buffer unit comprises a second pull-down element realized by a second MOS transistor which pull-down drives the period signal in response to the output signal of the first buffer unit, and a body of the second MOS transistor is coupled to the second resistor element.
